(19) United States
(12) Patent Application Publication
(10) Pub. No.: US 2026/0342296 A1
(43) Pub. Date: Oct. 29, 2026

(54) COMPUTATION CIRCUIT INCLUDING CORRECTION CIRCUIT, OPERATING METHOD THEREOF, AND SYSTEM INCLUDING SAME

(71) Applicants: SAMSUNG ELECTRONICS CO., LTD., Suwon-si (KR); KOREA ADVANCED INSTITUTE OF SCIENCE AND TECHNOLOGY, Daejeon (KR)

(72) Inventors: Kwangwoo LEE, Daejeon (KR); Wanyeong JUNG, Daejeon (KR)

(73) Assignees: SAMSUNG ELECTRONICS CO., LTD., Suwon-si (KR); KOREA ADVANCED INSTITUTE OF SCIENCE AND TECHNOLOGY, Daejeon (KR)

(21) Appl. No.: 19/656,376

(22) Filed: Apr. 23, 2026

(30) Foreign Application Priority Data
Apr. 28, 2025 (KR) 10-2025-0055803

(51) Int. Cl. H03F 3/45; G11C 11/408; H03G 3/30; H03M 1/38

(52) U.S. Cl. CPC H03F 3/45183; G11C 11/4085; H03G 3/30; H03M 1/38; H03F 2203/45156; H03G 2201/103; H03G 2201/70

(57) ABSTRACT

A computation circuit includes a capacitive circuit, a compute cell, and a correction circuit. The compute cell generates a differential output voltage by amplifying a differential input voltage with an amplification gain based on a capacitance of the capacitive circuit, and the correction circuit corrects the differential output voltage with a correction gain based on an average value of a first output voltage and a second output voltage of the compute cell forming the differential output voltage.

### CROSS-REFERENCE TO RELATED APPLICATION

This application is based on and claims priority under 35 U.S.C. § 119 to Korean Patent Application No. 10-2025-0055803, filed on Apr. 28, 2025, in the Korean Intellectual Property Office, the disclosure of which is incorporated by reference herein in its entirety.

### BACKGROUND

### 1. Field

The disclosure relates to a computation circuit, an operating method thereof, and a system including the same. More particularly, the disclosure relates to a computation circuit to which a correction algorithm for a high-accuracy computation result is applied.

### 2. Description of the Related Art

Neural network (NN)-based artificial intelligence (AI) technology is widely used in various fields such as image recognition, autonomous driving, and natural language processing. NNs operate by imitating neurons and synapses, and perform multiply-and-accumulate (MAC) computations in which input signals are multiplied by weights and then accumulated. For efficient MAC computation, processing-in-memory (PIM) technology is attracting attention.

Korean Patent Application Publication No. 10-2022-0149467 (Document 1) filed in the Korean Intellectual Property Office describes a semiconductor device that performs MAC computation. For example, Document 1 describes a semiconductor device in which all cell blocks perform computations by allocating input signals and weights to word lines and bit lines based on dynamic random access memory (DRAM)-based PIM technology.

However, related art PIM technology may degrade computation accuracy due to a transistor mismatch. In particular, threshold voltages of transistors are unevenly formed due to process errors or process-voltage-temperature (PVT) variations that occur during semiconductor manufacturing, which may cause computation errors.

### REFERENCE DOCUMENTS

### Patent Document

1. Korean Patent Publication No. 10-2022-0149467 filed in Korean Intellectual Property Office

### Non-Patent Documents

1. J. W. Jung and B. Razavi, “A 25-Gb/s 5-mWCMOS CDR/deserializer,” 2012 Symposium on VLSI Circuits (VLSIC), Honolulu, HI, USA, 2012, pp. 138-139, doi: 10.1109/VLSIC.2012.6243828.
2. B. Razavi, “Charge steering: A low-power design paradigm,′ Proceedings of the IEEE 2013 Custom Integrated Circuits Conference, San Jose, CA, USA, 2013, pp. 1-8, doi: 10.1109/CICC.2013.6658443.

### SUMMARY

Provided are a computation circuit performing computation with high accuracy, an operating method thereof, and a system including the same.

Additional aspects will be set forth in part in the description which follows and, in part, will be apparent from the description, or may be learned by practice of the presented embodiments of the disclosure.

According to an aspect of the disclosure, there is provided a computation circuit including: a capacitive circuit; a compute cell configured to generate a differential output voltage by amplifying a differential input voltage with a first gain based on a capacitance of the capacitive circuit, the differential output voltage including a first output voltage and a second output voltage; and a correction circuit configured to correct the differential output voltage with a second gain based on an average value of the first output voltage and the second output voltage of the compute cell.

The correction circuit may include an averaging circuit configured to generate an output voltage having the average value of the first output voltage and the second output voltage.

The averaging circuit may be configured to sequentially perform an operation of sampling the first output voltage, an operation of sampling the second output voltage, and an operation of generating the output voltage having an average value of the sampled first output voltage and the sampled second output voltage.

The averaging circuit may include: an inverter amplifier having an output terminal electrically connected to an output node providing the output voltage; a first capacitor electrically connected between a first input node receiving the first output voltage of the compute cell and an input terminal of the inverter amplifier; and a second capacitor electrically connected between a second input node receiving the second output voltage of the compute cell and the input terminal of the inverter amplifier.

The averaging circuit may include a first switch configured to connect the first input node of the averaging circuit to the first capacitor; a second switch configured to connect the second input node of the averaging circuit to the second capacitor; a third switch configured to connect a terminal of the first capacitor of the first input node and the output terminal of the inverter amplifier; a fourth switch configured to connect a terminal of the second capacitor of the second input node to the output terminal of the inverter amplifier; and a fifth switch configured to connect the input terminal of the inverter amplifier to the output terminal of the inverter amplifier.

The averaging circuit may be configured to: based on the first switch and the fifth switch being turned on, and the second switch, the third switch, and the fourth switch are turned off, sample the first output voltage, based on the second switch and the fifth switch being turned on, and the first switch, the third switch, and the fourth switch are turned off, sample the second output voltage, and based on the third switch and the fourth switch being turned on, and the first switch, the second switch, and the fifth switch are turned off, generate the output voltage having the average value of the first output voltage and the second output voltage.

The correction circuit may further include a gain correction circuit configured to receive the output voltage of the averaging circuit and correct the differential output voltage with the second gain based on the received output voltage.

The second gain corresponds to a difference between a supply voltage and the output voltage of the averaging circuit, and the gain correction circuit may be configured to generate an output signal corresponding to a value obtained by dividing the differential output voltage by the second gain.

The gain correction circuit may not include a divider.

The gain correction circuit may be configured to generate the output signal as a digital signal.

The gain correction circuit may include an analog-to-digital converter (ADC) configured to receive the first output voltage and the second output voltage of the compute cell, the output voltage of the averaging circuit, and the supply voltage, and to output the corrected differential output voltage as a digital signal. The ADC may be a successive approximation register (SAR)-ADC.

The second gain may correspond to a difference between a supply voltage of the computation circuit and the average value of the first output voltage and the second output voltage.

The differential input voltage may correspond to first input data, the capacitance of the capacitive circuit corresponds to second input data, and the corrected differential output voltage corresponds to a computation result of the first input data and the second input data.

According to another aspect of the disclosure, there is provided an operating method of a computation circuit including a capacitive circuit, a compute cell, and a correction circuit, the operating method including: adjusting capacitance of the capacitive circuit; generating, by the compute cell, a differential output voltage by amplifying a differential input voltage with a first gain based on a capacitance of the capacitive circuit, the differential output voltage including a first output voltage and a second output voltage; and correcting, by the correction circuit, the differential output voltage with a second gain based on an average value of the first output voltage and the second output voltage of the compute cell.

The correcting of the differential output voltage may include: generating, by a averaging circuit of the correction circuit, an output voltage having the average value of the first output voltage and the second output voltage; and receiving, by a gain correction circuit of the correction circuit, the output voltage of the averaging circuit and correcting, by the gain correction circuit, the differential output voltage with the second gain based on the received output voltage.

The generating the output voltage may include: sampling the first output voltage of the compute cell; sampling the second output voltage of the compute cell; and generating the output voltage having the average value of the sampled first output voltage and the sampled second output voltage.

The correcting the differential output voltage may include: generating an output signal corresponding to a value obtained by dividing the differential output voltage by the second gain, and wherein the second gain corresponds to a difference between a supply voltage and the output voltage of the averaging circuit.

According to another aspect of the disclosure, there is provided a system including: a processor; and a computation circuit communicatively coupled with the processor, wherein the computation circuit includes: a compute cell array including a plurality of compute cells each electrically connected to a first word line, a second word line, and a bit line; a word line driver configured to provide a differential input voltage to each of the plurality of compute cells through first word lines and second word lines; a plurality of capacitive circuits each electrically connected to a corresponding bit line; and a plurality of correction circuits each electrically connected to a corresponding bit line, wherein each of the plurality of compute cells is configured to: generate a differential output voltage by amplifying a corresponding differential input voltage with a first gain based on a capacitance of a corresponding capacitive circuit, among the plurality of capacitive circuits, the differential output voltage including a first output voltage and a second output voltage, and wherein each of the plurality of correction circuits is configured to: correct a corresponding differential output voltage with a second gain based on an average value of the first output voltage and the second output voltage of a corresponding compute cell.

Each of the plurality of compute cells may include a first memory cell electrically connected to a corresponding first word line and a corresponding bit line; and a second memory cell electrically connected to a corresponding second word line and the corresponding bit line.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates a computation circuit according to an embodiment;

FIGS. 2A, 2B and 2C are diagrams illustrating computation errors and a method of solving the computation errors;

FIG. 3A illustrates a computation circuit according to an embodiment;

FIG. 3B is a flowchart illustrating an operating method of a computation circuit, according to an embodiment;

FIG. 4 illustrates a correction circuit according to an embodiment;

FIG. 5A illustrates an averaging circuit according to an embodiment;

FIG. 5B illustrates an operating method of an averaging circuit, according to an embodiment;

FIG. 6A is a circuit diagram of a correction circuit and FIG. 6B is a diagram illustrating an operating method of the correction circuit, according to an embodiment;

FIGS. 7A and 7B are graphs illustrating accuracy of a computation result of a computation circuit according to embodiments;

FIG. 8 illustrates a computation circuit according to an embodiment;

FIG. 9 is a diagram illustrating an implementation example of a compute cell according to an embodiment; and

FIG. 10 illustrates a system according to an embodiment.

### DETAILED DESCRIPTION

Reference will now be made in detail to embodiments, examples of which are shown in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terms used in the disclosure are selected from commonly used terms as much as possible while considering the functions of this disclosure, but these may vary depending on the intention of engineers working in the field, precedents, the emergence of new technologies, etc. In addition, in certain cases, there are terms arbitrarily selected by the applicant, and in such cases, their meanings will be described in detail in the relevant description section. Therefore, the terms used in the disclosure should be defined based on the meaning of the terms and the overall details of the disclosure, rather than simply the names of the terms.

A singular expression may include a plural expression unless the context clearly indicates otherwise. Terms used herein, including technical or scientific terms, may have the same meaning as commonly understood by one of ordinary skill in the art described herein. In addition, the terms including ordinal numbers, such as ‘first’ or ‘second,’ used herein may be used to describe various components, but the components should not be limited by the terms. The above terms are used solely to distinguish one component from another.

When a part of the specification is said to “include” a component, this does not mean that it excludes other components, but rather that it may include other components, unless otherwise stated. In addition, the term “module” described in the specification refers to a unit that processes at least one function or operation, which may be implemented as hardware or software or a combination of hardware and software.

Below, with reference to the attached diagrams, embodiments of the disclosure are described in detail so that one of ordinary skill in the art may easily implement the disclosure. However, the disclosure may be implemented in many different forms and is not limited to the embodiments described herein.

Hereinafter, the disclosure will be described in detail with reference to the attached diagrams.

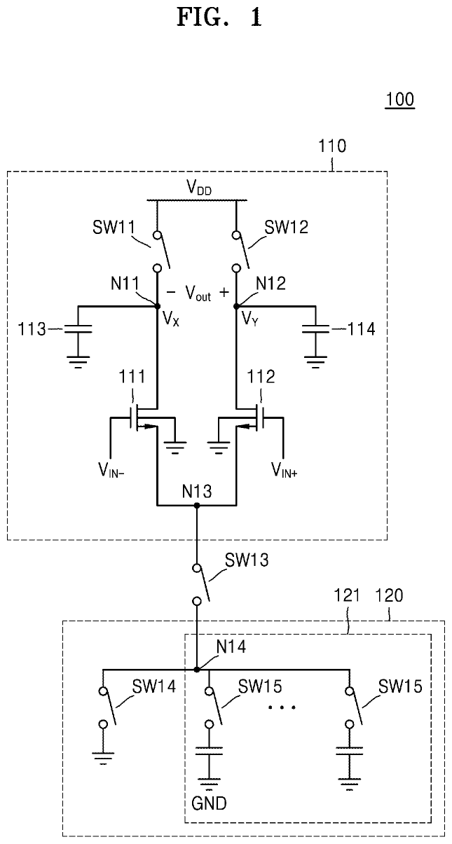

FIG. 1 illustrates a computation circuit 100 according to an embodiment.

The computation circuit 100 is a circuit that performs a computation of first input data and second input data. For example, the computation circuit 100 may be configured to perform a computation of first input data and second input data. The computation may be any one of a multiplication, multiply-and-accumulate (MAC), or an inner product, but is not limited thereto.

In an embodiment, the computation circuit 100 includes a compute cell 110, a capacitive circuit 120, and a switch SW13 (hereinafter referred to as a third switch SW13) connecting the compute cell 110 to the capacitive circuit 120. A first input voltage V_{IN-} and a second input voltage V_{IN+} may be input to the compute cell 110. The first input voltage V_{IN-} and the second input voltage V_{IN+} have a difference value corresponding to a value of the first input data. The capacitive circuit 120 may have capacitance corresponding to a value of the second input data.

The compute cell 110 includes a first transistor 111, a second transistor 112, a first capacitor 113, and a second capacitor 114. A drain terminal of the first transistor 111 is electrically connected to a first node N11, and a source terminal of the first transistor 111 is electrically connected to a third node N13. A drain terminal of the second transistor 112 is electrically connected to a second node N12, and a source terminal of the second transistor 112 is electrically connected to the third node N13. The first capacitor 113 is connected between the first node N11 and a ground GRD. The second capacitor 114 is connected between the second node N12 and the ground GRD.

The compute cell 110 may further include a first switch SW11 connecting the first node N11 to a supply voltage V_{DD} and a second switch SW12 connecting the second node N12 to the supply voltage V_{DD}.

The first input voltage V_{IN-} may be applied to a gate terminal of the first transistor 111. The second input voltage V_{IN+} may be applied to a gate terminal of the second transistor 112. The first input voltage V_{IN-} and the second input voltage V_{IN+} may be expressed by Equations 1 and 2, respectively.

$${V}_{IN -} = {V}_{C} - \frac{1}{2} {V}_{D} \qquad [ Equation 1 ]$$

$${V}_{IN +} = {V}_{C} + \frac{1}{2} {V}_{D} \qquad [ Equation 2 ]$$

Here, V_{C-} denotes a common mode voltage, and V_{D} denotes a differential input voltage.

The capacitive circuit 120 includes a capacitor bank 121 and a fourth switch SW14 connecting between the fourth node N14 and the ground GRD. The capacitor bank 121 may include a plurality of capacitors connected in parallel with each other and fifth switches SW15 connecting each of the capacitors to the fourth node N14. The capacitance of the capacitive circuit 120 may mean the capacitance of the capacitor bank 121 determined according to states of the fifth switches SW15. Therefore, the capacitance of the capacitive circuit 120 may be adjusted by turning on/off each of the fifth switches SW15.

The computation circuit 100 may operate in the order of a reset operation, a computation operation, and a preparation operation.

In the reset operation, the first switch SW11, the second switch SW12, the fourth switch SW14, and the fifth switches SW15 are turned on, and the third switch SW13 is turned off. Also, the first transistor 111 and the second transistor 112 are turned off. For example, a ground voltage may be provided to each of the gate terminals of the first transistor 111 and the second transistor 112. Accordingly, the first capacitor 113 and the second capacitor 114 are charged, and the capacitor bank 121 is discharged.

In the computation operation, the third switch SW13 is turned on, and the first switch SW11, the second switch SW12, and the fourth switch SW14 are turned off. In addition, the first input voltage V_{IN-} is applied to the gate terminal of the first transistor 111, and the second input voltage V_{IN+} is applied to the gate terminal of the second transistor 112. Here, the first input voltage V_{IN-} and the second input voltage V_{IN+} may be set so that the first transistor 111 and the second transistor 112 may operate in a saturation region, respectively. Each of the fifth switches SW15 is turned on or off according to the second input data. Accordingly, the capacitive circuit 120 has capacitance corresponding to the second input data.

According to non-patent documents 1 and 2, when the capacitance of each of the first capacitor 113 and the second capacitor 114 is C1 and the capacitance of the capacitive circuit 120 is C2, a differential output voltage V_{OUT} may be expressed as Equation 3. The differential output voltage V_{OUT} is a difference between a first output voltage V_{X} of the first node N11 and a second output voltage V_{Y} of the second node N12. It is assumed that the third switch SW13 is turned on and off for a preset time.

$${V}_{OUT} = K \times {V}_{D} \times \frac{C 2}{C 1} \qquad [ Equation 3 ]$$

Here, K denotes a constant. The differential input voltage V_{D} has the value corresponding to the first input data, and C2 has the value corresponding to the second input data. Accordingly, the differential output voltage V_{OUT} has a value obtained by multiplying a multiplication result of the first input data and the second input data by the constant.

In the preparation operation, the fourth switch SW14 and the fifth switches SW15 are turned on, and the first switch SW11, the second switch SW12, and the third switch SW13 are turned off. Also, the first transistor 111 and the second transistor 112 are turned off. For example, the ground voltage may be provided to the gate terminals of the first transistor 111 and the second transistor 112. Accordingly, the multiplication result is stored in the first capacitor 113 and the second capacitor 114.

The computation circuit 100 may repeatedly perform the computation operation and the preparation operation while changing the first input data and the second input data. Because the first transistor 111 and the second transistor 112 operate in the saturation region in the computation operation, when the computation operation and the preparation operation are repeatedly performed, the multiplication result may be overlappingly stored in the first capacitor 113 and the second capacitor 114. Accordingly, a MAC computation result may be stored in the first capacitor 113 and the second capacitor 114. The differential output voltage V_{OUT} corresponding to the MAC computation result may be expressed as Equation 4.

$${V}_{OUT} = {\sum }_{i} K \times {V}_{{D}_{i}} \times \frac{C {2}_{i}}{C 1} \qquad [ Equation 4 ]$$

In other words, the first input data and the second input data may be expressed as a first input vector and a second input vector, respectively, and the differential output voltage V_{OUT} may correspond to an inner product computation result of the first input vector and the second input vector.

As described above, the computation circuit 100 may perform a multiplication computation through the reset operation, the computation operation, and the preparation operation. In addition, the computation circuit 100 may perform the MAC computation by repeating the computation operation and the preparation operation after the reset operation. In addition, the computation circuit 100 may perform an inner product computation between vectors by repeating the computation operation and the preparation operation after the reset operation.

The computation circuit 100 may be configured as various circuits different from that shown in FIG. 1. For example, the computation circuit 100 may further include capacitors and switches for accumulating multiplication results. For example, the computation circuit 100 may include a switch connecting between the fourth node N14 and the supply voltage V_{DD} without including the first switch SW11 and the second switch SW12. For example, the computation circuit 100 may include a switch connecting between the third node N13 and the supply voltage V_{DD} without including the first switch SW11 and the second switch SW12. For example, the computation circuit 100 may further include a switch connecting the first node N11 to the drain terminal of the first transistor 111, a switch connecting the first node N11 to the drain terminal of the second transistor 112, a switch connecting the second node N12 to the drain terminal of the first transistor 111, and a switch connecting the second node N12 to the drain terminal of the second transistor 112.

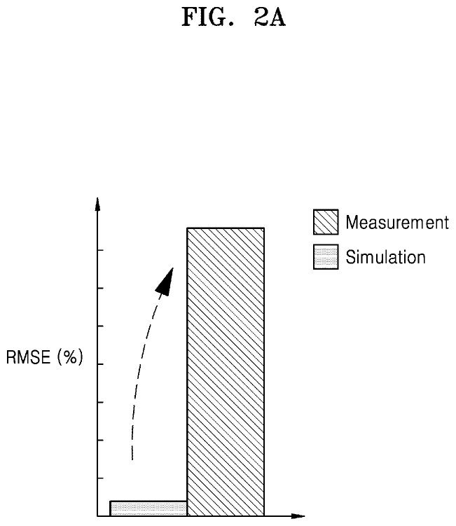

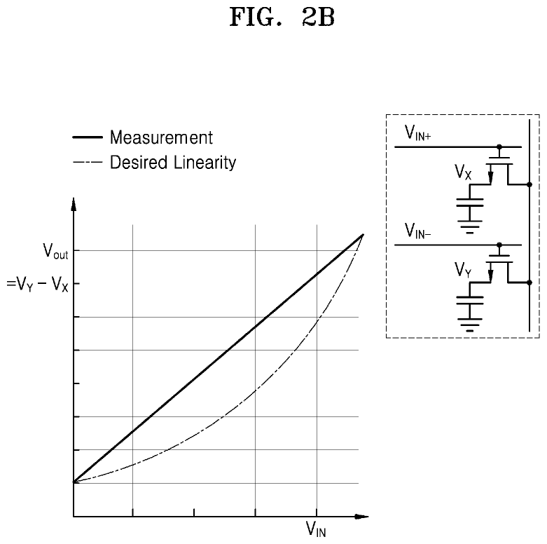

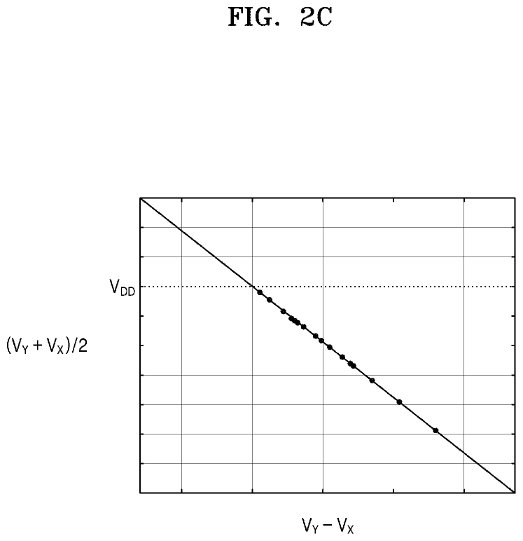

As described above, the differential output voltage V_{OUT} needs to satisfy Equation 3 or Equation 4, but when the computation circuit 100 is actually implemented, the differential output voltage V_{OUT} may not be satisfied due to various factors. For example, referring to FIG. 2A, a transistor mismatch may occur due to a process-voltage-temperature (PVT) variation, which may cause an error between a simulation result and a measurement result. In addition, referring to FIG. 2B, an error may occur in the measurement result due to a circuit nonlinearity caused by a capacitor discharge, etc.

FIG. 2C is a graph illustrating the relationship between a difference V_{Y}−V_{X} between a second output voltage V_{Y} and a first output voltage V_{X} and an average value (V_{Y}+V_{X})/2 of the first output voltage V_{X} and the second output voltage V_{Y} while changing threshold voltages of the first transistor 111 and the second transistor 112. From the graph of FIG. 2C, it may be seen that even though the threshold voltages of the first transistor 111 and the second transistor 112 change, there is a linear relationship between the difference V_{Y}−V_{X} between the second output voltage V_{Y} and the first output voltage V_{X} and the average value (V_{Y}+V_{X})/2 of the first output voltage V_{X} and the second output voltage V_{Y}. Therefore, it may be seen that an accurate computation result may be obtained robustly to the transistor mismatch by correcting a differential output voltage V_{OUT}=V_{Y}−V_{X} with a correction gain based on the average value (V_{Y}+V_{X})/2 of the first output voltage V_{X} and the second output voltage V_{Y}.

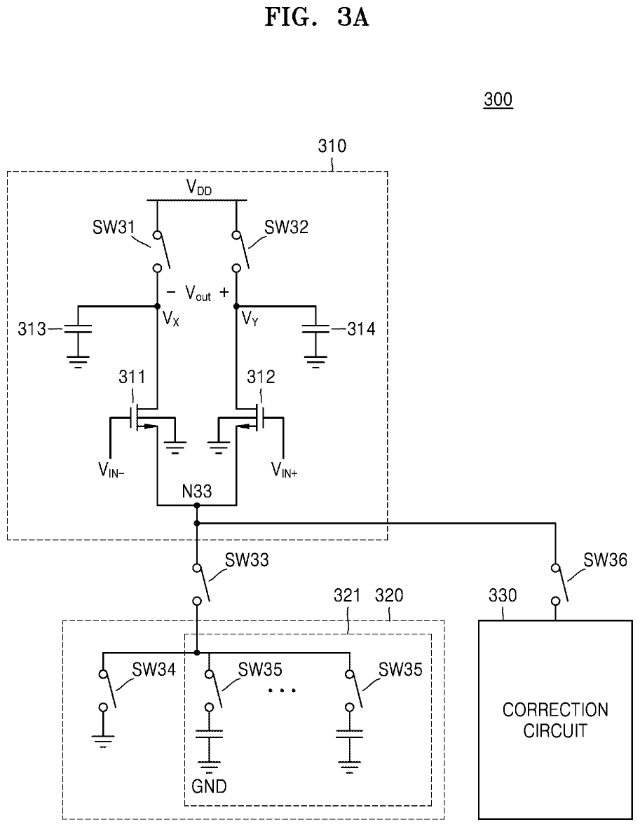

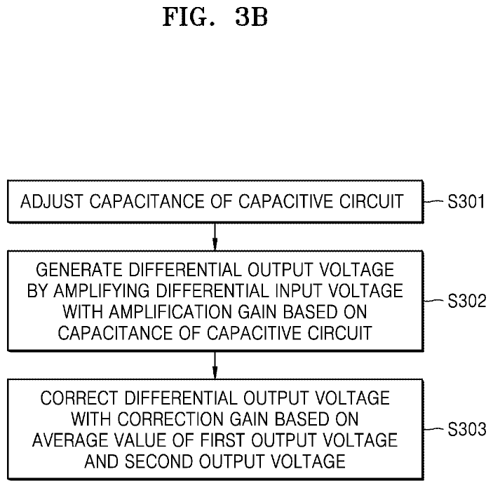

FIG. 3A illustrates a computation circuit 300 according to an embodiment.

The computation circuit 300 includes a compute cell 310, a capacitive circuit 320, and a correction circuit 330. In addition, the computation circuit 300 includes a third switch SW33 connecting the compute cell 310 to the capacitive circuit 320 and a sixth switch SW36 connecting the compute cell 310 to the correction circuit 330.

The compute cell 310 includes a first transistor 311, a second transistor 312, a first capacitor 313, and a second capacitor 314. The compute cell 310 may further include a first switch SW31 and a second switch SW32. The compute cell 310 is configured to generate the differential output voltage V_{OUT} by amplifying a differential input voltage V_{IN+}−V_{IN-} with an amplification gain based on the capacitance of the capacitive circuit 320. The description with reference to FIG. 1 may be applied to the compute cell 310, and redundant descriptions are omitted.

The capacitive circuit 320 includes a capacitor bank 321, a fourth switch SW34, and fifth switches SW35. The capacitance of the capacitive circuit 320 may be adjusted according to on/off of the fifth switches SW35. Descriptions with reference to FIG. 1 may be applied to the capacitive circuit 320, and redundant descriptions are omitted.

The correction circuit 330 is configured to generate an output signal corresponding to a computation result of first input data and second input data by correcting the differential output voltage V_{OUT}.

An equation model for correcting the differential output voltage V_{OUT} may be expressed as Equation 5.

V_{CORR_OUT}=f(V_{TH})×V_{OUT} [Equation 5]

Here, f(V_{TH}) denotes a voltage gain error, and V_{CORR_OUT} denotes a corrected differential output voltage.

From a linear relationship between the difference V_{Y}−V_{X} between the second output voltage V_{Y} and the first output voltage V_{X} and the average value (V_{Y}+V_{X})/2 of the first output voltage V_{X} and the second output voltage V_{Y}, Equation 5 may be expressed as Equation 6.

$${V}_{CORR \_ OUT} = \frac{{V}_{OUT}}{VDD - \frac{{V}_{Y} + {V}_{X}}{2}} \qquad [ Equation 6 ]$$

Here, V_{DD}−(V_{Y}+V_{X})/2 denotes a correction gain.

Equation 7 may be derived from Equations 3 and 6.

$${V}_{CORR \_ OUT} = \frac{K \times {V}_{D} \times \frac{C 2}{C 1}}{VDD - \frac{{V}_{Y} + {V}_{X}}{2}} \qquad [ Equation 7 ]$$

Equation 8 may be derived from Equations 4 and 6.

$${V}_{CORR \_ OUT} = \frac{{\sum }_{i} K \times {V}_{{D}_{i}} \times \frac{C {2}_{i}}{C 1}}{VDD - \frac{{V}_{{Y}_{i}} + {V}_{{X}_{i}}}{2}} \qquad [ Equation 8 ]$$

The correction circuit 330 may be variously configured to correct the differential output voltage V_{OUT} based on Equation 6. The output signal of the correction circuit 330 may correspond to the corrected differential output voltage V_{CORR_OUT}.

The correction circuit 330 may be configured to correct the differential output voltage V_{OUT} with the correction gain V_{DD}−(V_{Y}+V_{X})/2. For example, the correction circuit 330 may include various circuits for generating an average value of the first output voltage V_{X} and the second output voltage V_{Y}.

The correction circuit 330 may be configured to generate the output signal as a digital signal. In other words, the correction circuit 330 may be configured to generate the digital signal corresponding to the corrected differential output voltage V_{CORR_OUT}. For example, the correction circuit 330 may include various types of analog-to-digital converters (ADCs) such as a single-slope ADC (SS-ADC) or a delay-chain ADC.

The correction circuit 330 may be configured to generate an output signal corresponding to a value obtained by dividing the differential output voltage V_{OUT} by a correction gain. For example, the correction circuit 330 may include various types of dividers such as an analog divider or a digital divider. For example, the correction circuit 330 may include various types of ADCs without including a divider.

FIG. 3B is a flowchart illustrating an operating method of a computation circuit according to an embodiment.

Referring to FIGS. 3A and 3B together, in operation S301, the operating method may include adjusting the capacitance of the capacitive circuit 320. For example, the capacitive circuit 320 may be adjusted to have capacitance corresponding to a value of second input data. The capacitance of the capacitive circuit 320 may be adjusted by turning on/off each of the fifth switches SW35 according to the second input data.

In operation S302, the operating method may include generating the differential output voltage V_{OUT}. For example, the differential output voltage V_{OUT} may be generated by amplifying the differential input voltage V_{IN+}−V_{IN-} with an amplification gain based on the capacitance of the capacitive circuit 320. The first input voltage V_{IN-} and the second input voltage V_{IN+} having a difference corresponding to a value of first input data may be input to the compute cell 310. The compute cell 310 may operate according to the description with reference to FIG. 1, thereby generating a differential output voltage V_{--OUT}.

In operation S303, the operating method may include correcting the differential output voltage V₋₋ₒᵤₜ with a correction gain. For example, the correction gain is based on the average value (V_{Y}+V_{X})/2 of the first output voltage V_{X} and the second output voltage V_{Y}. The correction circuit 330 may generate an output signal corresponding to a computation result of the first input data and the second input data by obtaining the first output voltage V_{X} and the second output voltage V_{Y} from the compute cell 310 and correcting the differential output voltage V₋₋ₒᵤₜ with the correction gain.

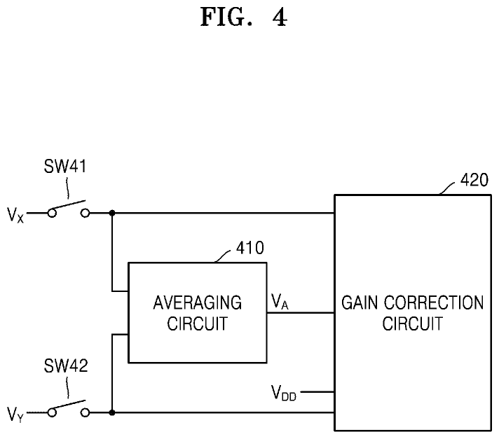

FIG. 4 illustrates a correction circuit 400 according to an embodiment. For example, FIG. 4 illustrates the correction circuit 400 configured to correct a differential output voltage V_{Y}−V_{X}=V_{OUT} based on Equation 6.

The correction circuit 400 includes an averaging circuit 410 and a gain correction circuit 420. The correction circuit 400 includes a first switch SW41 and a second switch SW42 that control the supply of the first output voltage V_{X} and the second output voltage V_{Y}, respectively.

The averaging circuit 410 is configured to generate an output voltage V_{A} corresponding to the average value (V_{Y}+V_{X})/2 of the first output voltage V_{X} and the second output voltage V_{Y}. The averaging circuit 410 may be implemented as various circuits for generating the average value (V_{Y}+V_{X})/2.

In an embodiment, the averaging circuit 410 may sample the first output voltage V_{X} while the first switch SW41 is turned on, and then sample the second output voltage V_{Y} while the second switch SW42 is turned on. Here, the sampling order of the first output voltage V_{X} and the second output voltage V_{Y} may be switched. Thereafter, the averaging circuit 410 may generate the output voltage V_{A} corresponding to the average value (V_{Y}+V_{X})/2 of the sampled first output voltage V_{X} and the sampled second output voltage V_{Y}.

The gain correction circuit 420 is configured to receive the output voltage V_{A} of the averaging circuit 410 and correct the differential output voltage V_{Y}−V_{X}=V_{OUT} with the correction gain based on the output voltage V_{A}. The gain correction circuit 420 may be implemented as various circuits. For example, the gain correction circuit 420 may include an analog divider, a digital divider, or an ADC.

In an embodiment, the gain correction circuit 420 may receive the supply voltage V_{DD} and the output voltage V_{A}. The gain correction circuit 420 may sample the first output voltage V_{X} while the first switch SW41 is turned on, and then sample the second output voltage V_{Y} while the second switch SW42 is turned on. Here, the sampling order of the first output voltage V_{X} and the second output voltage V_{Y} may be switched. In addition, the sampling timing of the first output voltage V_{X} and the second output voltage V_{Y} may be the same as that of the averaging circuit 410. The gain correction circuit 420 may generate an output signal corresponding to the corrected differential output voltage V_{CORR_OUT} of Equation 6 based on the received supply voltage V_{DD}, the output voltage V_{A}, the first output voltage V_{X} and the second output voltage V_{Y}.

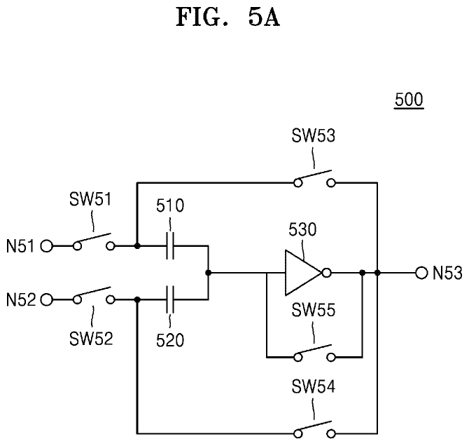

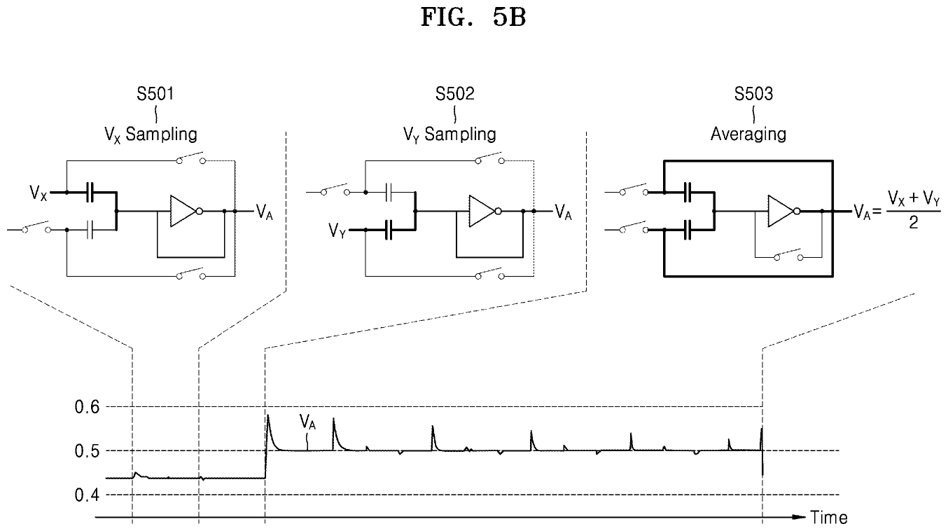

FIG. 5A illustrates an averaging circuit 500 according to an embodiment.

The averaging circuit 500 includes a first capacitor 510, a second capacitor 520, and an inverter amplifier 530. The first capacitor 510 is electrically connected between a first input node N51 and an input terminal of the inverter amplifier 530. The second capacitor 520 is electrically connected between a second input node N52 and the input terminal of the inverter amplifier 530.

The averaging circuit 500 may further include a first switch SW51, a second switch SW52, a third switch SW53, a fourth switch SW54, and a fifth switch SW55. The first switch SW51 connects the first input node N51 to the first capacitor 510. The second switch SW52 connects the second input node N52 to the second capacitor 520. The third switch SW53 connects a terminal of the first capacitor 510 on the side of the first input node N51 to an output terminal of the inverter amplifier 530. The fourth switch SW54 connects a terminal of the second capacitor 520 on the side of the second input node N52 to the output terminal of the inverter amplifier 530. The fifth switch SW55 connects the input terminal to the output terminal of the inverter amplifier 530.

FIG. 5B illustrates an operating method of the averaging circuit 500 according to an embodiment.

Referring to FIGS. 5A and 5B, in operation S501, the operating method may include sampling the first output voltage V_{X} of a compute cell. For example, the averaging circuit 500 samples the first output voltage V_{X} of a compute cell. In an example, case in which the first switch SW51 and the fifth switch SW55 are turned on, and the second switch SW52, the third switch SW53, and the fourth switch SW54 are turned off, the first output voltage V_{X} may be sampled by the first capacitor 510.

In operation S502, the operating method may include sampling the second output voltage V_{Y} of the compute cell. For example, the averaging circuit 500 samples the second output voltage V_{Y} of the compute cell. In an example case in which the second switch SW52 and the fifth switch SW55 are turned on, and the first switch SW51, the third switch SW53, and the fourth switch SW54 are turned off, the second output voltage V_{Y} may be sampled by the second capacitor 520.

In operation S503, the operating method may include averaging the first output voltage V_{X} and the second output voltage V_{Y}. For example, the averaging circuit 500 averages the first output voltage V_{X} and the second output voltage V_{Y}. In an example case in which the third switch SW53 and the fourth switch SW54 are turned on, and the first switch SW51, the second switch SW52, and the fifth switch SW55 are turned off, the output voltage V_{A} having the average value (V_{Y}+V_{X})/2 of the first output voltage V_{X} and the second output voltage V_{Y} may be generated.

The graph depicted in FIG. 5B shows an exemplary output voltage of an output node N53 of the averaging circuit 500. In an example case in which the first output voltage V_{X} of 0.6 V is sampled, and the second output voltage V_{Y} of 0.4 V is sampled, it may be seen that the output voltage V_{A} having 0.6 V that is the average value (V_{Y}+V_{X})/2 of the first output voltage V_{X} and the second output voltage V_{Y} is generated.

The inverter amplifier 530 may be implemented as several transistors, and thus the averaging circuit 500 may have a simple structure and may operate with low power consumption. In addition, as described with reference to FIG. 5B, the averaging circuit 500 may generate an average voltage through a simple operation. In addition, the averaging circuit 500 may provide the stable output voltage V_{A} by the inverter amplifier 530. Specifically, a voltage of the output terminal of the inverter amplifier 530 is determined as the average value (V_{Y}+V_{X})/2 of the sampled first output voltage V_{X} and the sampled second output voltage V_{Y}, and a voltage of the input terminal of the inverter amplifier 530 is fixed due to the first capacitor 510 and the second capacitor 520, and thus the output voltage V_{A} of the averaging circuit 500 may be stably maintained even when the averaging circuit 500 is connected to other circuits such as a gain correction circuit.

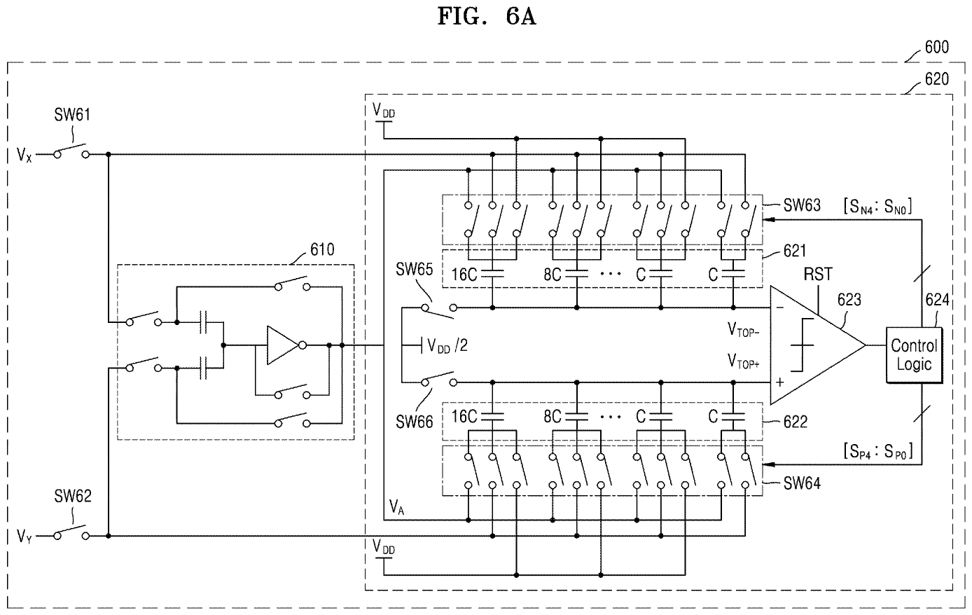

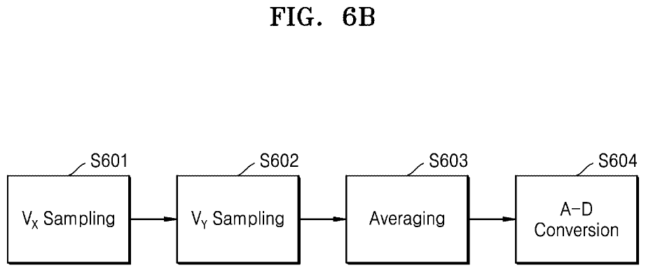

FIG. 6A is a circuit diagram of a circuit diagram of a correction circuit 600 and FIG. 6B illustrates an operating method of the correction circuit 600 according to an embodiment.

The correction circuit 600 includes an averaging circuit 610 and a gain correction circuit 620. In addition, the correction circuit 600 includes a first switch SW61 and a second switch SW62. Descriptions with reference to FIGS. 5A and 5B may be applied to the averaging circuit 610, and redundant descriptions are omitted.

The correction circuit 600 may be configured to generate an output signal as a digital signal. For example, as a non-limiting embodiment, the correction circuit 600 includes a gain correction circuit 620 implemented as a successive approximation register (SAR)-ADC. The gain correction circuit 620 generating an output signal of 5 bits is shown in FIG. 6A, but the number of bits is not limited thereto.

In the gain correction circuit 620, a fifth switch SW65 connects a common terminal of first capacitors 621 to an intermediate supply voltage V_{DD}/2. A sixth switch SW66 connects a common terminal of second capacitors 622 to the intermediate supply voltage V_{DD}/2.

The control logic 624 sequentially determines digital bits according to the output of a comparator 623, and controls third switches SW63 and fourth switches SW64. The supply voltage V_{DD}, the first output voltage V_{X}, or the output voltage V_{A} is provided to individual terminals of the first capacitors 621 according to on/off of the third switches SW63. The supply voltage V_{DD}, the second output voltage V_{Y}, or the output voltage V_{A} is provided to individual terminals of the second capacitors 622 according to on/off of the fourth switches SW64.

Each of the common terminal of the first capacitors 621 and the common terminal of the second capacitors 622 is connected to the comparator 623. The comparator 623 compares input signals V_{TOP-} and V_{TOP+} to generate an output signal.

FIG. 6B illustrates an operating method of the correction circuit 600 based on the averaging circuit 610 and the gain correction circuit 620 described above.

In operation S601, the operating method may include sampling the first output voltage Vₓ of a compute cell. For example, the averaging circuit 610 and the gain correction circuit 620 sample the first output voltage Vₓ of a compute cell. In an example case in which the first switch SW61 is turned on, and the second switch SW62 is turned off, each of the averaging circuit 610 and the gain correction circuit 620 may sample the first output voltage Vₓ.

In operation S602, the operating method may include sampling the second output voltage V_{Y} of the compute cell. For example, the averaging circuit 610 and the gain correction circuit 620 sample the second output voltage V_{Y} of the compute cell. In an example case in which the first switch SW61 is turned off, and the second switch SW62 is turned on, each of the averaging circuit 610 and the gain correction circuit 620 may sample the second output voltage V_{Y}.

In operation S603, the operating method may include averaging the first output voltage V_{X} and the second output voltage V_{Y}. For example, the averaging circuit 610 averages the first output voltage V_{X} and the second output voltage V_{Y}. Descriptions with reference to FIGS. 5A and 5B may be applied to operation S603.

In operation S604, the gain correction circuit 620 performs analog-to-digital conversion. The gain correction circuit 620 receives the output voltage V_{A} (i.e., the average value (V_{Y}+V_{X})/2 of the first output voltage V_{X} and the second output voltage V_{Y}) from the averaging circuit 610. The gain correction circuit 620 operates to convert a difference between the second output voltage V_{Y} and the first output voltage V_{X} into a digital signal in a range from the output voltage V_{A} (i.e., the average value (V_{Y}+V_{X})/2 of the first output voltage V_{X} and the second output voltage V_{Y}) to the supply voltage V_{DD}. Therefore, the output signal of the gain correction circuit 620 may be a digital signal corresponding to a corrected differential output signal of Equation 6. Accordingly, the correction circuit 600 may generate the corrected differential output signal according to Equation 6 without a divider.

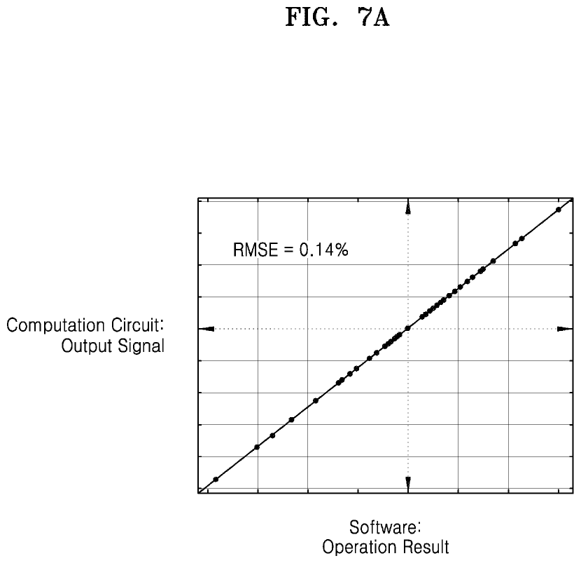

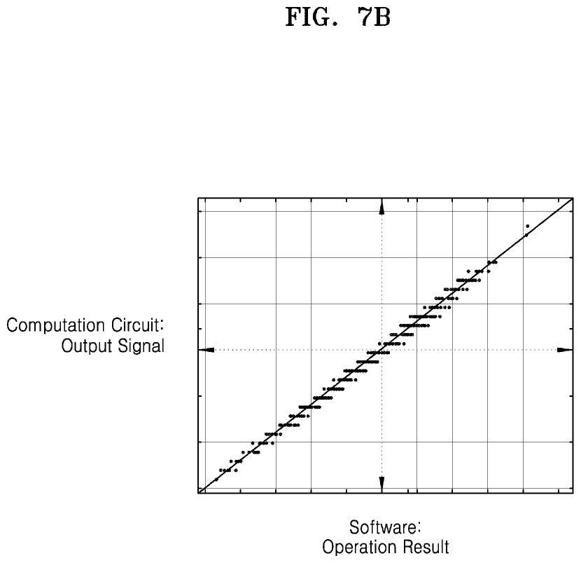

FIGS. 7A and 7B are graphs illustrating accuracy of a computation result of a computation circuit according to embodiments.

FIG. 7A is a graph comparing a MAC operation result of software with an analog output signal that is a MAC computation result of the computation circuit including a correction circuit according to the disclosure. From a root mean square error (RMSE) being 0.14%, it may be seen that the computation circuit provides a high-accuracy computation result.

FIG. 7B is a graph comparing a MAC operation result of software with a digital output signal that is a MAC computation result of the computation circuit including the correction circuit according to the disclosure. From the digital output signal graph of the computation circuit being similar to the operation result graph of the software, it may be seen that the computation circuit provides a high-accuracy computation result.

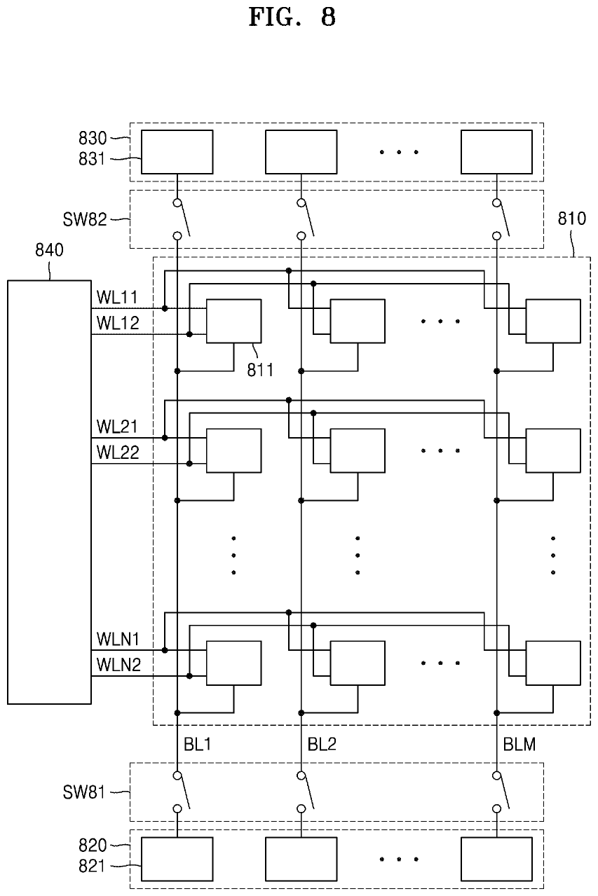

FIG. 8 illustrates a computation circuit 800 according to an embodiment.

The computation circuit 800 includes a compute cell array 810, a plurality of capacitive circuits 820, a plurality of correction circuits 830, and a word line driver 840. Descriptions of the disclosure may be applied to the compute cell array 810, the capacitive circuits 820, and the correction circuits 830, and redundant descriptions are omitted.

The compute cell array 810 includes a plurality of compute cells each electrically connected to a first word line, a second word line, and a bit line. For example, a compute cell 811 in a first row and a first column is electrically connected to a first word line WL11, a second word line WL12, and a bit line BL1.

The word line driver 840 is configured to provide a differential input voltage to each compute cell through the first word line and the second word line. For example, a first input voltage may be applied to the compute cell 811 through the first word line WL11, and a second input voltage may be applied to the compute cell 811 through the second word line WL12. The magnitude of the differential input voltage provided to each row may be different. That is, the magnitude of an input voltage provided to each word line may be different. The word line driver 840 may control the magnitude and timing of the differential input voltage provided to each row. That is, the word line driver 840 may control the magnitude and timing of each of the first input voltage and the second input voltage provided to each word line.

The word line driver 840 may include a first voltage generation circuit and a second voltage generation circuit. The first voltage generation circuit may generate the first input voltage corresponding to first input data. The second voltage generation circuit may generate the second input voltage corresponding to second input data. The word line driver 840 may further include a switching circuit. The switching circuit may include switches connecting each of the first voltage generation circuit and the second voltage generation circuit to the first word line or the second word line, such that the first input data is provided to the first word line or the second word line, and the second input data is provided to the first word line or the second word line.

A capacitive circuit corresponding to each bit line is connected. For example, a capacitive circuit 821 is electrically connected to the bit line BL1. The connection between the plurality of capacitive circuits 820 and the compute cell array 810 may be controlled by first switches SW81.

A correction circuit corresponding to each bit line is connected. For example, a correction circuit 831 is electrically connected to the bit line BL1. The connection between the plurality of correction circuits 830 and the compute cell array 810 may be controlled by second switches SW82.

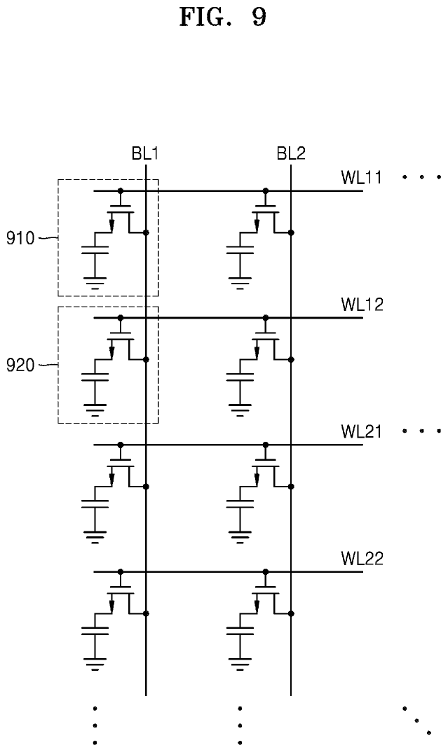

FIG. 9 is a diagram illustrating an implementation example of a compute cell according to an embodiment.

FIG. 9 schematically illustrates a memory cell array of a dynamic random access memory (DRAM). One compute cell may be implemented using two memory cells 910 and 920 that share the same bit line. For example, the first transistor 311 and the first capacitor 313 of FIG. 3A may be implemented by the first memory cell 910, and the second transistor 312 and the second capacitor 314 may be implemented by the second memory cell 920. As described above, a computation circuit of the disclosure may be implemented using the memory cell array of the existing DRAM.

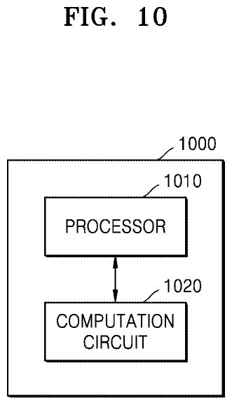

FIG. 10 illustrates a system 1000 according to an embodiment.

The system 1000 includes a processor 1010 and a computation circuit 1020 communicatively coupled with the processor 1010. The description given above may be applied to the computation circuit 1020, and redundant descriptions are omitted.

The processor 1010 may be configured to control an operation of the computation circuit 1020. For example, the processor 1010 may be configured to process an output signal of the computation circuit 1020. For example, the processor 1010 may be a field-programmable gate array (FPGA) or a microcontroller (MCU), but is not limited thereto.

At least some of hardware components of the system 1000 may be mounted on a semiconductor chip. The system 1000 may be applied to a computation device, a robot, a smart TV, a smartphone, a medical device, a mobile device, an image display device, a measurement device, an Internet of Things (IoT) device, etc., and may be applied to various electronic devices.

The system 1000 may further include, as a non-limiting example, at least one of a memory, an input/output module, a security module, a sensor module, or a communication module.

The memory may be configured to store one or more instructions. For example, the memory may be on-chip memory, cache memory, random access memory (RAM), read only memory (ROM), flash memory, solid state drive (SSD), hard disk drive (HDD), or optical disk drive (ODD), but is not limited thereto.

The processor 1010 may be configured to execute the one or more instructions stored in the memory to control the operation of the system 1000. For example, the processor 1010 may be a central processing unit (CPU), an application processor (AP), a digital signal processor (DSP), a graphics processing unit (GPU), a vision processing unit (VPU), or a natural processing unit (NPU), but is not limited thereto.

The sensor module may collect peripheral information of the system 1000. For example, the sensor module may include at least one of a microphone, an imaging device, an image sensor, a light detection and ranging (LIDAR) sensor, an ultrasound sensor, an infrared sensor, a biosensor, or a touch sensor, but is not limited thereto.

The communication module may include various wired or wireless interfaces through which the system 1000 may communicate with an external device. As a non-limiting example, the communication module may include a communication interface capable of connecting to a wired local area network (LAN), a wireless local area network (WLAN) such as wireless fidelity (WiFi), a wireless personal area network (WPAN) such as Bluetooth, a wireless universal serial bus (USB), Zigbee, near field communication (NFC), radio-frequency identification (RFID), power line communication (PLC), or a mobile cellular network such as 3rd Generation (3G), 4th Generation (4G), long term evolution (LTE), and 5th Generation (5G).

The circuits of the disclosure may be modified in various forms to perform the described operation. For example, some switches may be omitted or added to the circuits of the disclosure.

The above description of the disclosure is for illustrative purposes only, and a person having ordinary skill in the art to which the disclosure pertains will understand that the disclosure may be easily modified into other specific forms without changing the technical idea or essential characteristics of the disclosure. Therefore, it should be understood that the embodiments described above are examples in all respects and not limiting. For example, each component described as a single entity may be implemented in a distributed manner, and likewise, components described as distributed may be implemented in a combined manner.

The scope of the disclosure is indicated by the claims described below rather than the detailed description above, and all changes or modifications derived from the meaning and scope of the claims and their equivalent concepts should be interpreted as being included in the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A computation circuit comprising:
a capacitive circuit;
a compute cell configured to generate a differential output voltage by amplifying a differential input voltage with a first gain based on a capacitance of the capacitive circuit, the differential output voltage comprising a first output voltage and a second output voltage; and
a correction circuit configured to correct the differential output voltage with a second gain based on an average value of the first output voltage and the second output voltage of the compute cell.

2. The computation circuit of claim 1, wherein the correction circuit comprises an averaging circuit configured to generate an output voltage having the average value of the first output voltage and the second output voltage.

3. The computation circuit of claim 2, wherein the averaging circuit is configured to sequentially perform an operation of sampling the first output voltage, an operation of sampling the second output voltage, and an operation of generating the output voltage having an average value of the sampled first output voltage and the sampled second output voltage.

4. The computation circuit of claim 2, wherein the averaging circuit comprises:
an inverter amplifier having an output terminal electrically connected to an output node providing the output voltage;
a first capacitor electrically connected between a first input node receiving the first output voltage of the compute cell and an input terminal of the inverter amplifier; and
a second capacitor electrically connected between a second input node receiving the second output voltage of the compute cell and the input terminal of the inverter amplifier.

5. The computation circuit of claim 4, wherein the averaging circuit comprises:
a first switch configured to connect the first input node of the averaging circuit to the first capacitor;
a second switch configured to connect the second input node of the averaging circuit to the second capacitor;
a third switch configured to connect a terminal of the first capacitor of the first input node and the output terminal of the inverter amplifier;
a fourth switch configured to connect a terminal of the second capacitor of the second input node to the output terminal of the inverter amplifier; and
a fifth switch configured to connect the input terminal of the inverter amplifier to the output terminal of the inverter amplifier.

6. The computation circuit of claim 5, wherein the averaging circuit is configured to:
based on the first switch and the fifth switch being turned on, and the second switch, the third switch, and the fourth switch are turned off, sample the first output voltage,
based on the second switch and the fifth switch being turned on, and the first switch, the third switch, and the fourth switch are turned off, sample the second output voltage, and
based on the third switch and the fourth switch being turned on, and the first switch, the second switch, and the fifth switch are turned off, generate the output voltage having the average value of the first output voltage and the second output voltage.

7. The computation circuit of claim 2, wherein the correction circuit further comprises a gain correction circuit configured to receive the output voltage of the averaging circuit and correct the differential output voltage with the second gain based on the received output voltage.

8. The computation circuit of claim 7, wherein
the second gain corresponds to a difference between a supply voltage and the output voltage of the averaging circuit, and
the gain correction circuit is configured to generate an output signal corresponding to a value obtained by dividing the differential output voltage by the second gain.

9. The computation circuit of claim 8, wherein the gain correction circuit does not include a divider.

10. The computation circuit of claim 8, wherein the gain correction circuit is configured to generate the output signal as a digital signal.

11. The computation circuit of claim 8, wherein
the gain correction circuit comprises an analog-to-digital converter (ADC) configured to receive the first output voltage and the second output voltage of the compute cell, the output voltage of the averaging circuit, and the supply voltage, and to output the corrected differential output voltage as a digital signal.

12. The computation circuit of claim 11, wherein the ADC is a successive approximation register (SAR)-ADC.

13. The computation circuit of claim 1, wherein the second gain corresponds to a difference between a supply voltage of the computation circuit and the average value of the first output voltage and the second output voltage.

14. The computation circuit of claim 1, wherein the differential input voltage corresponds to first input data, the capacitance of the capacitive circuit corresponds to second input data, and the corrected differential output voltage corresponds to a computation result of the first input data and the second input data.

15. An operating method of a computation circuit including a capacitive circuit, a compute cell, and a correction circuit, the operating method comprising:
adjusting capacitance of the capacitive circuit;
generating, by the compute cell, a differential output voltage by amplifying a differential input voltage with a first gain based on a capacitance of the capacitive circuit, the differential output voltage comprising a first output voltage and a second output voltage; and
correcting, by the correction circuit, the differential output voltage with a second gain based on an average value of the first output voltage and the second output voltage of the compute cell.

16. The operating method of claim 15, wherein the correcting of the differential output voltage comprises:
generating, by a averaging circuit of the correction circuit, an output voltage having the average value of the first output voltage and the second output voltage; and
receiving, by a gain correction circuit of the correction circuit, the output voltage of the averaging circuit and correcting, by the gain correction circuit, the differential output voltage with the second gain based on the received output voltage.

17. The operating method of claim 16, wherein the generating the output voltage comprises:
sampling the first output voltage of the compute cell;
sampling the second output voltage of the compute cell; and
generating the output voltage having the average value of the sampled first output voltage and the sampled second output voltage.

18. The operating method of claim 16, wherein the correcting the differential output voltage comprises:
generating an output signal corresponding to a value obtained by dividing the differential output voltage by the second gain, and
wherein the second gain corresponds to a difference between a supply voltage and the output voltage of the averaging circuit.

19. A system comprising:
a processor; and
a computation circuit communicatively coupled with the processor,
wherein the computation circuit comprises:
a compute cell array comprising a plurality of compute cells each electrically connected to a first word line, a second word line, and a bit line;
a word line driver configured to provide a differential input voltage to each of the plurality of compute cells through first word lines and second word lines;
a plurality of capacitive circuits each electrically connected to a corresponding bit line; and
a plurality of correction circuits each electrically connected to a corresponding bit line,
wherein each of the plurality of compute cells is configured to:
generate a differential output voltage by amplifying a corresponding differential input voltage with a first gain based on a capacitance of a corresponding capacitive circuit, among the plurality of capacitive circuits, the differential output voltage comprising a first output voltage and a second output voltage, and
wherein each of the plurality of correction circuits is configured to:
correct a corresponding differential output voltage with a second gain based on an average value of the first output voltage and the second output voltage of a corresponding compute cell.

20. The system of claim 19, wherein each of the plurality of compute cells comprises:
a first memory cell electrically connected to a corresponding first word line and a corresponding bit line; and
a second memory cell electrically connected to a corresponding second word line and the corresponding bit line.
